(19) United States
(12) Patent Application Publication
(10) Pub. No.: US 2024/0014353 A1
(43) Pub. Date: Jan. 11, 2024

(54) DISPLAY DEVICE AND METHOD OF MANUFACTURING THE SAME

(71) Applicant: Samsung Display Co., LTD., Yongin-si (KR)

(72) Inventors: Joon Yong PARK, Yongin-si (KR); Sung Joo KWON, Yongin-si (KR); Hyun Eok SHIN, Yongin-si (KR); Dong Min LEE, Yongin-si (KR); Yung Bin CHUNG, Yongin-si (KR)

(73) Assignee: Samsung Display Co., LTD., Yongin-si (KR)

(21) Appl. No.: 18/109,322

(22) Filed: Feb. 14, 2023

(30) Foreign Application Priority Data
Jul. 7, 2022 (KR) 10-2022-0084032

(51) Int. Cl. H01L 33/38; H01L 33/62; H01L 33/42; H01L 33/00; H01L 25/075

(52) U.S. Cl. CPC H01L 33/387; H01L 33/62; H01L 33/42; H01L 33/005; H01L 25/0753; H01L 2933/0016; H01L 2933/0066

(57) ABSTRACT

A display device includes electrodes on a base layer; a first insulating layer on the electrodes; a light emitting element on the first insulating layer; and a connection electrode electrically connecting the light emitting element and at least a portion of the electrodes. Each of the electrodes includes a first layer and a second layer on the first layer. The first layer is electrically connected to the connection electrode through a contact portion formed in a region penetrating the first insulating layer and the second layer.

### CROSS-REFERENCE TO RELATED APPLICATION

The application claims priority to and the benefit of Korean Patent Application No. 10-2022-0084032 under 35 U.S.C. § 119, filed Jul. 7, 2022, in the Korean Intellectual Property Office (KIPO), the entire contents which are incorporated herein by reference.

### BACKGROUND

### 1. Technical Field

The disclosure relates to a display device and a method of manufacturing the same.

### 2. Description of the Related Art

In recent years, as interest in information displays increases, research and development on display devices are continuously being made.

### SUMMARY

An objective of the disclosure is to provide a display device capable of preventing damage to electrodes and improving reliability of an electrical signal, and a method of manufacturing the same.

The technical objectives to be achieved by the disclosure are not limited to those described herein, and other technical objectives that are not mentioned herein would be clearly understood by a person skilled in the art from the description of the disclosure.

A display device according to one or more embodiments of the disclosure may include electrodes on a base layer; a first insulating layer on the electrodes; a light emitting element on the first insulating layer; and a connection electrode electrically connecting the light emitting element and at least a portion of the electrodes. Each of the electrodes may include a first layer and a second layer on the first layer. The first layer may be electrically connected to the connection electrode through a contact portion formed in a region penetrating the first insulating layer and the second layer.

According to one or more embodiments, the first layer may be more adjacent to the base layer than the second layer. The second layer may be more adjacent to the light emitting element than the first layer. The first layer and the second layer may contact with each other.

According to one or more embodiments, the second layer may expose a region of the first layer. The connection electrode may physically contact with the first layer in the region.

According to one or more embodiments, the connection electrode may not physically contact the second layer in a region adjacent to the region.

According to one or more embodiments, the display device may further include a second insulating layer on the first insulating layer. The second insulating layer may cover a side surface of the first insulating layer and the second layer in a region adjacent to the region of the first layer exposed by the second layer.

According to one or more embodiments, a first thickness of the first layer may be greater than a second thickness of the second layer.

According to one or more embodiments, the first thickness may be at least twice the second thickness.

According to one or more embodiments, the first thickness may be in a range of about 1000 Å to about 4000 Å. The second thickness may be in a range of about 100 Å to about 500 Å.

According to one or more embodiments, the first layer may include at least one selected from a group consisting of molybdenum (Mo), molybdenum-niobium (MoNb), and molybdenum-tungsten (MoW).

According to one or more embodiments, the second layer may include at least one selected from a group consisting of aluminum (Al), aluminum-titanium (AlTi), and aluminum-neodymium (AlNd).

According to one or more embodiments, the connection electrode may include at least one selected from a group consisting of indium tin oxide (ITO), indium zinc oxide (IZO), and indium tin zinc oxide (ITZO).

According to one or more embodiments, a corrosion potential of a material for forming the first layer and a corrosion potential of a material for forming the connection electrode may be different by a potential difference. The potential difference may be about 1.0V or less.

According to one or more embodiments, the potential difference may be in a range of about 0.2V to about 0.6V.

According to one or more embodiments, a resistance value between the first layer and the connection electrode may be about 10³Ω or less.

A display device according to one or more embodiments of the disclosure may include electrodes on a base layer and including a first layer and a second layer; a first insulating layer on the electrodes; a light emitting element on the first insulating layer; a second insulating layer on the first insulating layer; and a connection electrode electrically connecting the electrodes and the light emitting element. The second layer and the first insulating layer may form a hole exposing the first layer. The second insulating layer may cover a side surface of the first insulating layer and the second layer adjacent to the hole. The connection electrode may not physically contact with the second layer, without being physically contacted with the first layer through a contact portion formed in the hole.

A method of manufacturing a display device according to one or more embodiments of the disclosure may include patterning electrodes on a base layer; disposing a first insulating layer on the electrodes; disposing a light emitting element on the first insulating layer; and patterning a connection electrode electrically connecting the light emitting element and the electrodes. The patterning the electrodes may include sequentially patterning a first layer and a second layer. The patterning the connection electrode may include electrically connecting the connection electrode to the first layer through a contact portion formed in a region penetrating the first insulating layer and the second layer.

According to one or more embodiments, the electrodes may include a first electrode and a second electrode spaced apart from the first electrode. The disposing of the light emitting element may include supplying a first alignment signal to the first electrode and supplying a second alignment signal to the second electrode; and aligning the light emitting element between the first electrode and the second electrode based on an electric field according to the first alignment signal and the second alignment signal.

According to one or more embodiments, the method of manufacturing the display device may further include forming a first hole by the first insulating layer; forming a second hole by the second layer; disposing a second insulating layer on the first insulating layer; and forming a third hole by the second insulating layer. The disposing of the second insulating layer may include covering a side surface of the second layer and the first insulating layer by the second insulating layer in a region adjacent to the second hole. The forming of the third hole may include exposing the first layer by the second insulating layer.

According to one or more embodiments, the method of manufacturing the display device may further include forming a bank on the first insulating layer. The forming of the bank and the forming the first hole may be performed in a same process.

According to one or more embodiments, a corrosion potential of a material for forming the first layer and a corrosion potential of a material for forming the connection electrode may be different by a potential difference. The potential difference may be about 1.0V or less.

### BRIEF DESCRIPTION OF THE DRAWINGS

The accompanying drawings, which are included to provide a further understanding of the disclosure, and are incorporated in and constitute a part of this specification, illustrate embodiments of the disclosure, and, together with the description, serve to explain principles of the disclosure.

FIG. 1 is a perspective view schematically illustrating a light emitting element according to one or more embodiments.

FIG. 2 is a cross-sectional view schematically illustrating the light emitting element according to one or more embodiments.

FIG. 3 is a plan view schematically illustrating a display device according to one or more embodiments.

FIG. 4 is a plan view schematically illustrating a sub-pixel according to one or more embodiments.

FIG. 5 is a cross-sectional view schematically illustrating the sub-pixel according to one or more embodiments.

FIG. 6 is a cross-sectional view schematically illustrating a pixel according to one or more embodiments.

FIG. 7 is a cross-sectional view schematically illustrating a sub-pixel according to one or more embodiments.

FIG. 8 is a cross-sectional view schematically illustrating an alignment electrode according to one or more embodiments.

FIG. 9 is an enlarged view schematically illustrating area EA1 of FIG. 5.

FIGS. 10 to 24 are cross-sectional views schematically illustrating a method of manufacturing a display device according to one or more embodiments in each process step.

### DETAILED DESCRIPTION OF THE EMBODIMENTS

As the disclosure allows for various changes and numerous embodiments, particular embodiments will be illustrated in the drawings and described in detail in the written description. However, this is not intended to limit the disclosure to particular modes of practice, and it is to be appreciated that all changes, equivalents, and substitutes that do not depart from the features and technical scope of the disclosure are encompassed in the disclosure.

It will be understood that, although the terms “first”, “second”, and the like may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular expressions are intended to include the plural expressions as well, unless the context clearly indicates otherwise.

It will be further understood that the terms “comprise”, “include”, “have”, etc. used in the disclosure, specify the presence of stated features, integers, steps, operations, elements, components, or combinations of them but do not preclude the presence or addition of one or more other features, integers, steps, operations, elements, components, or combinations thereof. In addition, when a first part such as a layer, film, region, plate, etc. is “on” a second part, the first part may be not only “directly on” the second part but a third part may intervene between them. Furthermore, in the disclosure, when a first part such as a layer, film, region, plat, etc. is formed on a second part, a direction in which the first part is formed is not limited to an upper direction of the second part, but may include a side or a lower direction of the second part. To the contrary, when a first part such as a layer, film, region, plate, etc. is “under” a second part, the first part may be not only “directly under” the second part but a third part may intervene between them.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. It may also be understood that if one part and another part are connected, they may or may not be integral with each other.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure relates to a display device and a method of manufacturing the same. Hereinafter, a display device and a method of manufacturing the same according to embodiments will be described with reference to the accompanying drawings.

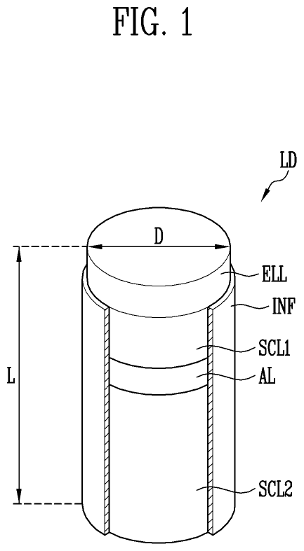

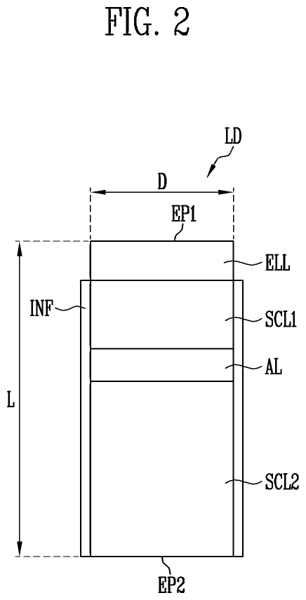

A light emitting element LD according to embodiments will be described with reference to FIGS. 1 and 2. FIG. 1 is a perspective view schematically illustrating a light emitting element according to an embodiment. FIG. 2 is a cross-sectional view schematically illustrating the light emitting element according to an embodiment.

According to embodiments, the light emitting element LD may be configured to emit light. For example, the light emitting element LD may be a light emitting diode including an inorganic material.

The light emitting element LD may have various shapes. For example, the light emitting element LD may have a shape extending in a direction. According to embodiments, FIGS. 1 and 2 illustrate the light emitting element LD having a columnar shape. However, the type and shape of the light emitting element LD are not limited to the above-described examples.

The light emitting element LD may include a first semiconductor layer SCL1, a second semiconductor layer SCL2, and an active layer AL disposed between the first and second semiconductor layers SCL1 and SCL2. For example, in case that a direction in which the light emitting element LD extends is referred to as a length L direction, the light emitting element LD may include the first semiconductor layer SCL1, the active layer AL, and the second semiconductor layer SCL2 sequentially stacked each other in the length L direction. The light emitting element LD may further include an electrode layer ELL and an element insulating film INF.

The light emitting element LD may be provided in a columnar shape extending in a direction. The light emitting element LD may have a first end EP1 and a second end EP2. The first semiconductor layer SCL1 may be adjacent to the first end EP1 of the light emitting element LD, and the second semiconductor layer SCL2 may be adjacent to the second end EP2 of the light emitting element LD. The electrode layer ELL may be adjacent to the first end EP1.

The light emitting element LD may be a light emitting element manufactured in a columnar shape through an etching process. The columnar shape may include a rod-like shape or a bar-like shape elongated in the length L direction (for example, having an aspect ratio greater than about 1), such as a cylinder or polygonal column, and the shape of the cross-section thereof is not particularly limited. For example, the length L of the light emitting element LD may be greater than the diameter D (or the width of the cross-section).

The light emitting element LD may have a size of nano-scale to micro-scale. For example, the light emitting element LD may have the diameter D (or width) and/or the length L ranging from nano-scale to micro-scale. However, the size of the light emitting element LD is not limited thereto.

The first semiconductor layer SCL1 may be a semiconductor layer of a first conductivity type. The first semiconductor layer SCL1 may be disposed on the active layer AL and may include a semiconductor layer of a different type from that of the second semiconductor layer SCL2. For example, the first semiconductor layer SCL1 may include a P-type semiconductor layer. For example, the first semiconductor layer SCL1 may include a P-type semiconductor layer including at least one semiconductor material of InAlGaN, GaN, AlGaN, InGaN, AlN, and InN and doped with a first conductivity type dopant such as Mg or the like. However, the material constituting the first semiconductor layer SCL1 is not limited thereto, and various other materials may be used to form the first semiconductor layer SCL1.

The active layer AL may be disposed between the first semiconductor layer SCL1 and the second semiconductor layer SCL2, and may have a single-quantum well structure or a multi-quantum well structure. The position of the active layer AL is not limited to a specific example, and may be variously changed according to the type of the light emitting element LD.

A clad layer doped with a conductive dopant may be formed on upper and/or lower portions of the active layer AL. For example, the clad layer may be formed as (or formed of) an AlGaN layer or an InAlGaN layer. According to embodiments, a material such as AlGaN, InAlGaN, or the like may be used to form the active layer AL, and various other materials may be used to form the active layer AL. However, the embodiments are not limited thereto.

The second semiconductor layer SCL2 may be a semiconductor layer of a second conductivity type. The second semiconductor layer SCL2 may be disposed on the active layer AL and may include a semiconductor layer of a different type from that of the first semiconductor layer SCL1. For example, the second semiconductor layer SCL2 may include an N-type semiconductor layer. For example, the second semiconductor layer SCL2 may include an N-type semiconductor layer including at least one semiconductor material of InAlGaN, GaN, AlGaN, InGaN, AlN, and InN and doped with a second conductivity type dopant such as Si, Ge, Sn, or the like. However, the material constituting the second semiconductor layer SCL2 is not limited thereto, and various other materials may be used to form the second semiconductor layer SCL2.

In case that a voltage equal to or greater than a threshold voltage is applied to ends of the light emitting element LD, the light emitting element LD may emit light while electron-hole pairs are combined in the active layer AL. By controlling the light emitting of the light emitting element LD by using this principle, the light emitting element LD may be used as a light source of various light emitting devices including pixels of a display device.

The element insulating film INF may be disposed on a surface of the light emitting element LD. The element insulating film INF may be formed on the surface of the light emitting element LD to surround at least the outer surface of the active layer AL. The element insulating film INF may further surround portions of the first and second semiconductor layers SCL1 and SCL2. The element insulating film INF may be formed as a single layer or a double layer, but the disclosure is not limited thereto, and may include films. For example, the element insulating film INF may include a first insulating film including a first material and a second insulating film including a second material different from the first material.

The element insulating film INF may expose ends of the light emitting element LD having different polarities. For example, the element insulating film INF may expose one end of each of the electrode layer ELL and the second semiconductor layer SCL2 adjacent to the first and second ends EP1 and EP2 of the light emitting element LD.

The element insulating film INF may include an insulating material, e.g., at least one of silicon oxide (SiOx), silicon nitride (SiNx), silicon oxynitride (SiOxNy), aluminum oxide (AlOx), and titanium oxide (TiOx). The element insulating film INF may have a single-layer or multi-layer structure. However, the disclosure is not limited to the above-described examples. For example, according to another embodiment, the formation of the element insulating film INF may be omitted.

According to embodiments, in case that the element insulating film INF is provided to cover the surface of the light emitting element LD, particularly, the outer surface of the active layer AL, electrical stability of the light emitting element LD can be secured. In case that the element insulating film INF is provided on the surface of the light emitting element LD, lifespan and efficiency can be improved by minimizing surface defects of the light emitting element LD. Even in case that light emitting elements LD are disposed adjacent to each other, it is possible to prevent an unwanted short circuit between the light emitting elements LD.

The electrode layer ELL may be disposed on the first semiconductor layer SCL1. The electrode layer ELL may be adjacent to the first end EP1. The electrode layer ELL may be electrically connected to the first semiconductor layer SCL1.

A portion of the electrode layer ELL may be exposed. For example, the element insulating film INF may expose a surface of the electrode layer ELL. The electrode layer ELL may be exposed in a region corresponding to the first end EP1.

According to embodiments, a side surface of the electrode layer ELL may be exposed. For example, the element insulating film INF may cover side surfaces of the first semiconductor layer SCL1, the active layer AL, and the second semiconductor layer SCL2, but may not cover at least a portion of the side surface of the electrode layer ELL. Electrical connection between the electrode layer ELL adjacent to the first end EP1 and other components may be easy. According to embodiments, the element insulating film INF may expose a portion of the side surface of the first semiconductor layer SCL1 and/or the second semiconductor layer SCL2 as well as the side surface of the electrode layer ELL.

According to embodiments, the electrode layer ELL may be an ohmic contact electrode. However, the disclosure is not limited to the above-described examples. For example, the electrode layer ELL may be a Schottky contact electrode.

According to embodiments, the electrode layer ELL may include at least one of chromium (Cr), titanium (Ti), aluminum (Al), gold (Au), nickel (Ni), an oxide thereof, or an alloy thereof. However, the disclosure is not limited to the above-described examples. According to embodiments, the electrode layer ELL may be substantially transparent. For example, the electrode layer ELL may include indium tin oxide (ITO). Accordingly, the emitted light may pass through the electrode layer ELL.

The structure and shape of the light emitting element LD are not limited to the above-described examples. According to embodiments, the light emitting element LD may have various structures and shapes. For example, the light emitting element LD may further include an additional electrode layer disposed on a surface of the second semiconductor layer SCL2 and adjacent to the second end EP2.

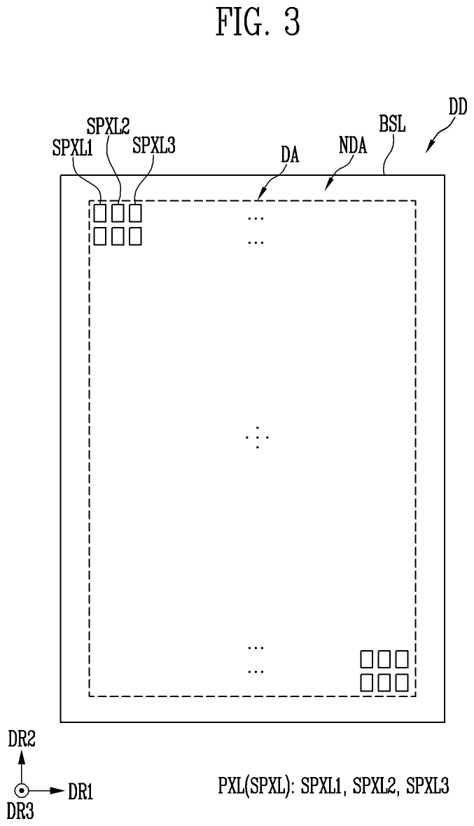

FIG. 3 is a plan view schematically illustrating a display device according to an embodiment.

Referring to FIG. 3, a display device DD may include a base layer BSL and a pixel PXL disposed on the base layer BSL. Although not shown in the drawings, the display device DD may further include a driving circuit part (for example, a scan driver and a data driver) for driving the pixel PXL, wirings, and pads.

The display device DD may include a display area DA and a non-display area NDA. The non-display area NDA may refer to an area excluding the display area DA. The non-display area NDA may surround at least a portion of the display area DA.

The base layer BSL may form a base member of the display device DD. The base layer BSL may be a rigid or flexible substrate or film. For example, the base layer BSL may be a rigid substrate made of glass or tempered glass, a flexible substrate (or thin film) made of plastic or metal, or at least one insulating layer. The material and/or properties of the base layer BSL are not particularly limited. In embodiments, the base layer BSL may be substantially transparent. The term “substantially transparent” may mean that light can be transmitted with a transmittance or more (e.g., a predetermined or selectable transmittance or more). In another embodiment, the base layer BSL may be translucent or opaque. The base layer BSL may include a reflective material according to embodiments.

The display area DA may refer to an area in which the pixel PXL is disposed. The non-display area NDA may refer to an area in which the pixel PXL is not disposed. The driving circuit part, the wirings, and the pads electrically connected to the pixel PXL of the display area DA may be disposed in the non-display area NDA.

According to an example, the pixel PXL (or sub-pixels SPXL) may be arranged according to a stripe or PENTILE™ arrangement structure. However, the disclosure is not limited thereto, and various embodiments may be applied to the disclosure.

According to embodiments, the pixel PXL (or sub-pixels SPXL) may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. The first sub-pixel SPXL1, the second sub-pixel SPXL2, and the third sub-pixel SPXL3 may form a pixel part configured to emit light of various colors.

For example, each of the first sub-pixel SPXL1, the second sub-pixel SPXL2, and the third sub-pixel SPXL3 may emit light of a color (e.g., a predetermined or selectable color). For example, the first sub-pixel SPXL1 may be a red pixel emitting red (for example, a first color) light, the second sub-pixel SPXL2 may be a green pixel emitting green (for example, a second color) light, and the third sub-pixel SPXL3 may be a blue pixel emitting blue (for example, a third color) light. According to embodiments, the number of second sub-pixels SPXL2 may be greater than the number of first sub-pixels SPXL1 and the number of third sub-pixels SPXL3. However, the color, type and/or number of the first sub-pixels SPXL1, the second sub-pixels SPXL2, and the third sub-pixels SPXL3 constituting the pixel part are not limited to specific examples.

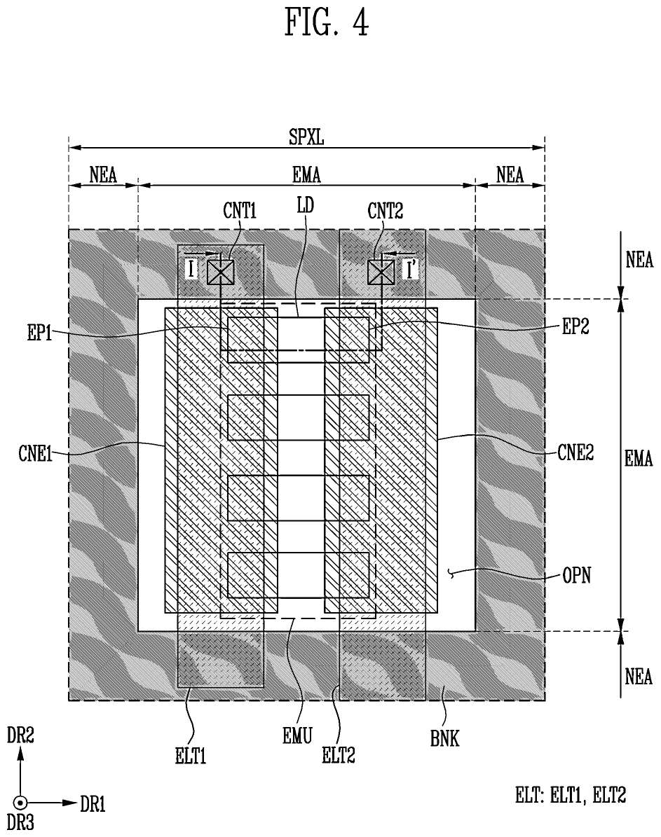

The pixel PXL (or sub-pixel SPXL) according to embodiments will be described with reference to FIGS. 4 to 7. FIGS. 4 to 7 are schematic diagrams illustrating the pixel PXL (or sub-pixel SPXL) according to embodiments. Repetitive contents with respect to the above-described contents will be briefly described or will not be repeatedly described.

First, a planar structure of the sub-pixel SPXL will be described with reference to FIG. 4. FIG. 4 is a plan view schematically illustrating a sub-pixel according to an embodiment. The sub-pixel SPXL shown in FIG. 4 may be at least one of the first to third sub-pixels SPXL1, SPXL2, and SPXL3 described above with reference to FIG. 3.

The sub-pixel SPXL may include an emission area EMA and a non-emission area NEA. The sub-pixel SPXL may include a bank BNK, an alignment electrode ELT, the light emitting element LD, a first connection electrode CNE1, and a second connection electrode CNE2.

The emission area EMA may overlap an opening OPN defined by the bank BNK in a plan view. Light emitting elements LD may be disposed in the emission area EMA.

The light emitting elements LD may not be disposed in the non-emission area NEA. A portion of the non-emission area NEA may overlap the bank BNK in a plan view.

The bank BNK may form (or provide) the opening OPN. For example, the bank BNK may have a shape that protrudes in a thickness direction (for example, a third direction DR3) of the base layer BSL and surrounds a region (e.g., a predetermined or selectable region). Accordingly, the opening OPN in which the bank BNK is not disposed may be formed.

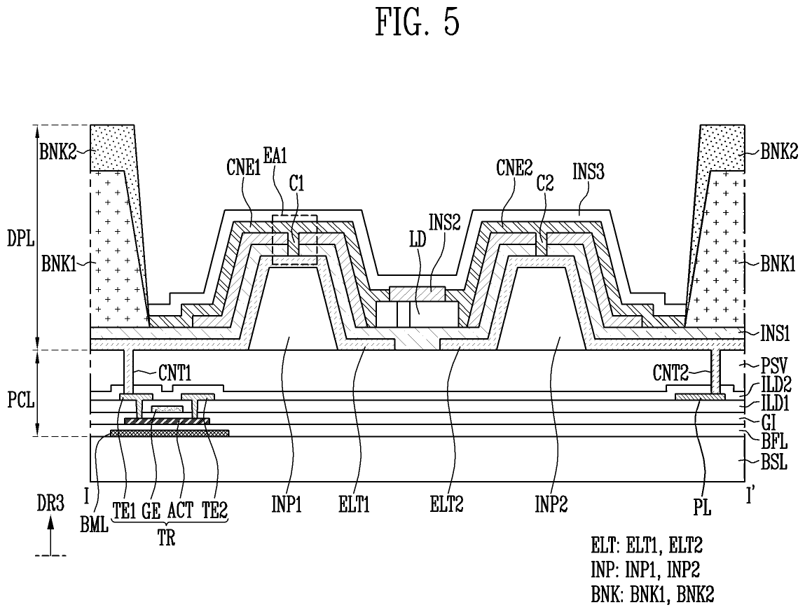

The bank BNK may form a space. The bank BNK may have a shape surrounding a region in a plan view. The space may mean a region in which a fluid may be accommodated. According to embodiments, the bank BNK may include a first bank BNK1 and a second bank BNK2 (see FIG. 5).

According to embodiments, by providing ink, including the light emitting element LD, in the space defined by the bank BNK (for example, the first bank BNK1), the light emitting element LD may be disposed in the opening OPN.

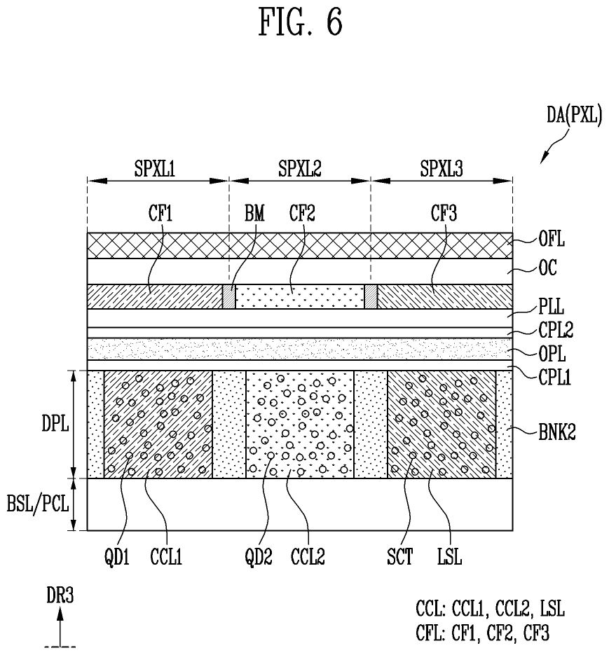

According to embodiments, a color conversion layer CCL (see FIG. 6) may be disposed (or patterned) in the space defined by the bank BNK (for example, the second bank BNK2).

The bank BNK may define the emission area EMA and the non-emission area NEA. The bank BNK may surround at least a portion of the emission area EMA in a plan view. For example, an area in which the bank BNK is disposed may be the non-emission area NEA. As an area in which the bank BNK is not disposed, the area in which the light emitting element LD is disposed may be the emission area EMA.

The alignment electrode ELT may be an electrode for aligning the light emitting element LD. The alignment electrode ELT may be an electrode for supplying an electrical signal to the connection electrodes CNE1 and CNE2. According to embodiments, the alignment electrode ELT may include a first electrode ELT1 and a second electrode ELT2. The alignment electrode ELT may be referred to as an “electrode” or “electrodes”.

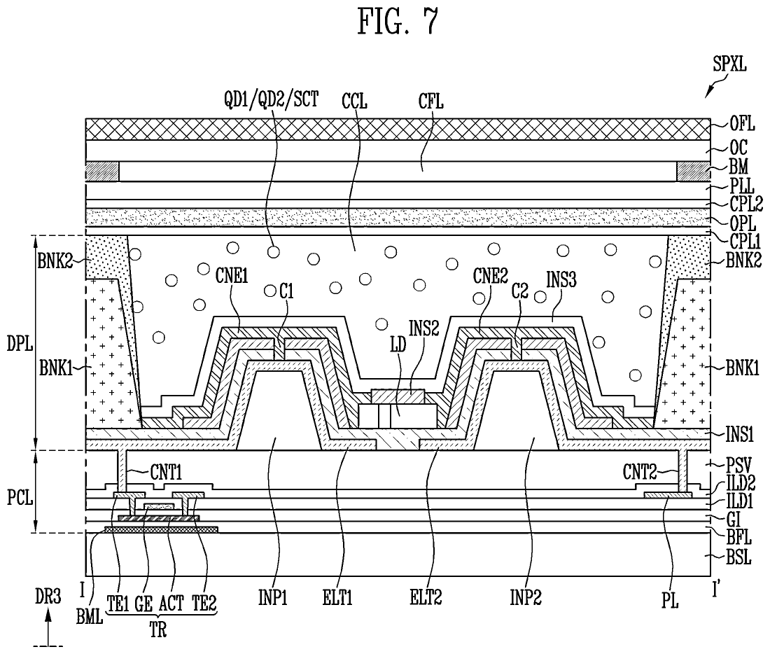

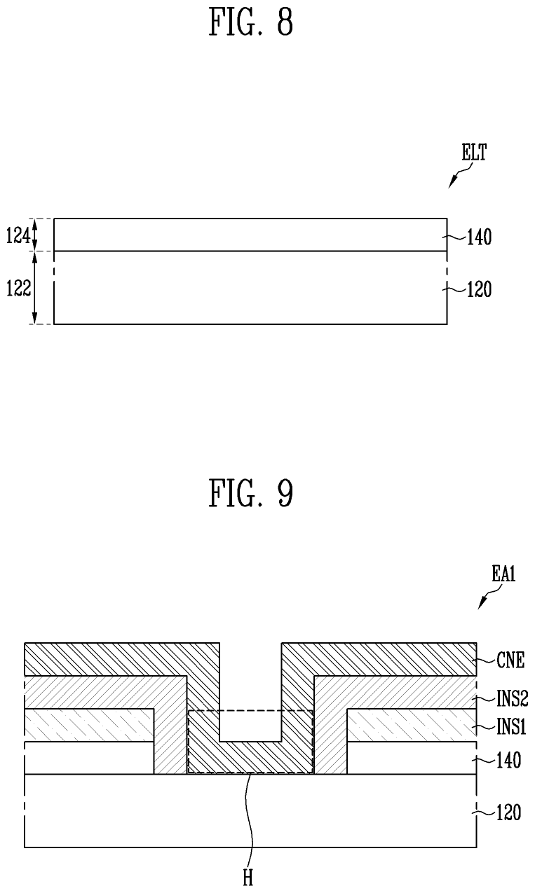

The alignment electrode ELT may include a conductive material, and the alignment electrode ELT may have a multi-layer structure. For example, the alignment electrode ELT may include a first layer 120 and a second layer 140 (see FIG. 8). This will be described below with reference to FIG. 8.

The light emitting element LD may be disposed on the alignment electrode ELT. According to embodiments, at least a portion of the light emitting element LD may be disposed between the first electrode ELT1 and the second electrode ELT2. The light emitting element LD may be aligned between the first electrode ELT1 and the second electrode ELT2. The light emitting elements LD may form (or constitute) an emission part EMU. The emission part EMU may refer to a part including light emitting elements LD adjacent to each other.

According to embodiments, the light emitting element LD may be aligned in various ways. For example, FIG. 4 illustrates an embodiment in which the light emitting elements LD are arranged in parallel between the first electrode ELT1 and the second electrode ELT2. However, the disclosure is not limited to the above-described examples. For example, the light emitting elements LD may be arranged in a series structure or a series/parallel mixed structure, and the number of parts connected in series and/or in parallel is not particularly limited.

The first electrode ELT1 and the second electrode ELT2 may be spaced apart from each other. For example, the first electrode ELT1 and the second electrode ELT2 may be spaced apart from each other in a first direction DR1 in the emission area EMA and may extend in a second direction DR2.

According to embodiments, the first electrode ELT1 and the second electrode ELT2 may be electrodes for aligning the light emitting element LD. The first electrode ELT1 may be a first alignment electrode, and the second electrode ELT2 may be a second alignment electrode.

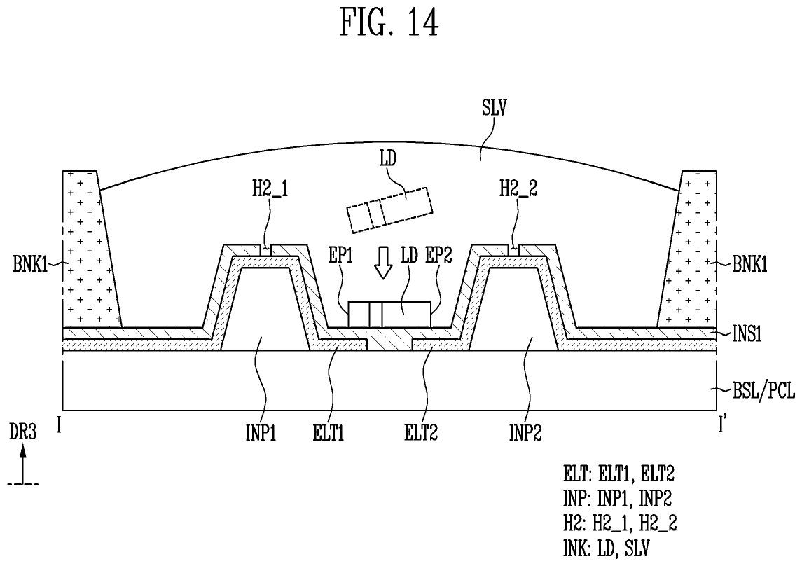

The first electrode ELT1 and the second electrode ELT2 may receive a first alignment signal and a second alignment signal, respectively, in a process step in which the light emitting elements LD are aligned. For example, ink INK (see FIG. 14) including the light emitting element LD may be supplied (or provided) to the opening OPN defined by the bank BNK (for example, the first bank BNK1), the first alignment signal may be supplied to the first electrode ELT1, and the second alignment signal may be supplied to the second electrode ELT2. The first alignment signal and the second alignment signal may have different waveforms, potentials, and/or phases. For example, the first alignment signal may be an AC signal, and the second alignment signal may be a ground signal. However, the disclosure is not limited to the above-described examples. An electric field may be formed between (or on) the first electrode ELT1 and the second electrode ELT2, and the light emitting elements LD may be aligned between the first electrode ELT1 and the second electrode ELT2 based on the electric field. For example, the light emitting elements LD may be moved (or rotated) by a force (for example, a dielectrophoresis (DEP) force) according to the electric field and aligned (or disposed) on the alignment electrode ELT.

The first electrode ELT1 may be electrically connected to a circuit element (for example, a transistor TR (see FIG. 5)) through a first contact member CNT1. According to embodiments, the first electrode ELT1 may provide an anode signal so that the light emitting element LD emits light. The first electrode ELT1 may provide the first alignment signal for aligning the light emitting element LD.

The second electrode ELT2 may be electrically connected to a power source line PL (see FIG. 5) through a second contact member CNT2. According to embodiments, the second electrode ELT2 may provide a cathode signal so that the light emitting element LD emits light. The second electrode ELT2 may provide the second alignment signal for aligning the light emitting element LD.

Positions of the first contact member CNT1 and the second contact member CNT2 are not limited to the positions shown in FIG. 4 and may be appropriately changed in various ways.

The light emitting element LD may emit light based on the provided electrical signal. For example, the light emitting element LD may emit light based on a first electrical signal (for example, the anode signal) provided from the first connection electrode CNE1 and a second electrical signal (for example, the cathode signal) provided from the second connection electrode CNE2.

The first end EP1 of the light emitting element LD may be disposed adjacent to the first electrode ELT1, and the second end EP2 of the light emitting element LD may be disposed adjacent to the second electrode ELT2. The first end EP1 may or may not overlap the first electrode ELT1. The second end EP2 may or may not overlap the second electrode ELT2.

According to embodiments, the first end EP1 of each of the light emitting elements LD may be electrically connected to the first electrode ELT1 through the first connection electrode CNE1. Similarly, the second end EP2 of each of the light emitting elements LD may be electrically connected to the second electrode ELT2 through the second connection electrode CNE2.

The first connection electrode CNE1 and the second connection electrode CNE2 may be disposed on first ends EP1 and second ends EP2 of the light emitting elements LD, respectively.

The first connection electrode CNE1 may be disposed on the first ends EP1 to be electrically connected to the first ends EP1 of the light emitting elements LD. In an embodiment, the first connection electrode CNE1 may be disposed on the first electrode ELT1 to be electrically connected to the first electrode ELT1. The first ends EP1 of the light emitting elements LD may be connected to the first electrode ELT1 through the first connection electrode CNE1. The first connection electrode CNE1 may be physically spaced apart from the second layer 140 of the first electrode ELT1, and may be electrically connected to the first layer 120.

The second connection electrode CNE2 may be disposed on the second ends EP2 to be electrically connected to the second ends EP2 of the light emitting elements LD. In an embodiment, the second connection electrode CNE2 may be disposed on the second electrode ELT2 to be electrically connected to the second electrode ELT2. The second ends EP2 of the light emitting elements LD may be connected to the second electrode ELT2 through the second connection electrode CNE2. The second connection electrode CNE2 may be physically spaced apart from the second layer 140 of the second electrode ELT2, and may be electrically connected to the first layer 120.

A cross-sectional structure of the pixel PXL (or sub-pixel SPXL) according to embodiments will be described with reference to FIGS. 5 to 7. A pixel circuit layer PCL and a display element layer DPL of the sub-pixel SPXL will be described with reference to FIG. 5. An optical layer OPL, a color filter layer CFL, and an outer film layer OFL will be described with reference to FIGS. 6 and 7. Repetitive contents with respect to the above-described contents will be briefly described or will not be repeatedly described.

FIG. 5 is a cross-sectional view schematically illustrating the sub-pixel according to an embodiment. FIG. 6 is a cross-sectional view schematically illustrating a pixel according to an embodiment. FIG. 7 is a cross-sectional view schematically illustrating a sub-pixel according to an embodiment.

Referring to FIG. 5, the sub-pixel SPXL may be disposed on the base layer BSL. The sub-pixel SPXL may include the pixel circuit layer PCL and the display element layer DPL.

The base layer BSL may form a base member on which the sub-pixel SPXL is to be formed. The base layer BSL may provide an area in which the pixel circuit layer PCL and the display element layer DPL are to be disposed.

The pixel circuit layer PCL may be disposed on the base layer BSL. The pixel circuit layer PCL may include a lower auxiliary electrode BML, a buffer layer BFL, the transistor TR, a gate insulating layer GI, a first interlayer insulating layer ILD1, a second interlayer insulating layer ILD2, and a passivation layer PSV.

The lower auxiliary electrode BML may be disposed on the base layer BSL. The lower auxiliary electrode BML may function as a path through which an electrical signal is transmitted. According to embodiments, a portion of the lower auxiliary electrode BML may overlap the transistor TR in a plan view.

The buffer layer BFL may be disposed on the base layer BSL. The buffer layer BFL may cover the lower auxiliary electrode BML. The buffer layer BFL may prevent impurities from diffusing from outside. The buffer layer BFL may include at least one of silicon oxide (SiOx), silicon nitride (SiNx), silicon oxynitride (SiOxNy), aluminum oxide (AlOx), and titanium oxide (TiOx). However, the disclosure is not limited to the above-described examples.

The transistor TR may be a thin-film transistor. According to embodiments, the transistor TR may be a driving transistor. The transistor TR may be electrically connected to the light emitting element LD. The transistor TR may be electrically connected to the first end EP1 of the light emitting element LD.

The transistor TR may include an active layer ACT, a first transistor electrode TE1, a second transistor electrode TE2, and a gate electrode GE.

The active layer ACT may refer to a semiconductor layer. The active layer ACT may be disposed on the buffer layer BFL. The active layer ACT may include at least one selected from the group consisting of polysilicon, low-temperature polycrystalline silicon (LTPS), amorphous silicon, and an oxide semiconductor.

The active layer ACT may include a first contact region contacting the first transistor electrode TE1 and a second contact region contacting the second transistor electrode TE2. The first contact region and the second contact region may be semiconductor patterns doped with impurities. A region between the first contact region and the second contact region may be a channel region. The channel region may be an intrinsic semiconductor pattern not doped with impurities.

The gate electrode GE may be disposed on the gate insulating layer GI. The position of the gate electrode GE may correspond to the position of the channel region of the active layer ACT. For example, the gate electrode GE may be disposed on the channel region of the active layer ACT with the gate insulating layer GI interposed therebetween.

The gate insulating layer GI may be disposed on the buffer layer BFL. The gate insulating layer GI may cover the active layer ACT. The gate insulating layer GI may include at least one of silicon oxide (SiOx), silicon nitride (SiNx), silicon oxynitride (SiOxNy), aluminum oxide (AlOx), and titanium oxide (TiOx). However, the disclosure is not limited to the above-described examples.

The first interlayer insulating layer ILD1 may be disposed on the gate insulating layer GI. The first interlayer insulating layer ILD1 may cover the gate electrode GE. The first interlayer insulating layer ILD1 may include at least one of silicon oxide (SiOx), silicon nitride (SiNx), silicon oxynitride (SiOxNy), aluminum oxide (AlOx), and titanium oxide (TiOx). However, the disclosure is not limited to the above-described examples.

The first transistor electrode TE1 and the second transistor electrode TE2 may be disposed on the first interlayer insulating layer ILD1. The first transistor electrode TE1 may pass through the gate insulating layer GI and the first interlayer insulating layer ILD1 to contact the first contact region of the active layer ACT. The second transistor electrode TE2 may pass through the gate insulating layer GI and the first interlayer insulating layer ILD1 to contact the second contact region of the active layer ACT. For example, the first transistor electrode TE1 may be a drain electrode and the second transistor electrode TE2 may be a source electrode, but the disclosure is not limited thereto.

The first transistor electrode TE1 may be electrically connected to the first electrode ELT1 through the first contact member CNT1 penetrating the passivation layer PSV and the second interlayer insulating layer ILD2.

The power source line PL may be disposed on the first interlayer insulating layer ILD1. According to embodiments, the power source line PL, the first transistor electrode TE1, and the second transistor electrode TE2 may be disposed on a same layer. The power source line PL may be electrically connected to the second electrode ELT2 through the second contact member CNT2. The power source line PL may supply a power source or an alignment signal through the second electrode ELT2.

The second interlayer insulating layer ILD2 may be disposed on the first interlayer insulating layer ILD1. The second interlayer insulating layer ILD2 may cover the first transistor electrode TE1, the second transistor electrode TE2, and the power source line PL. The second interlayer insulating layer ILD2 may include at least one of silicon oxide (SiOx), silicon nitride (SiNx), silicon oxynitride (SiOxNy), aluminum oxide (AlOx), and titanium oxide (TiOx). However, the disclosure is not limited to the above-described examples.

The passivation layer PSV may be disposed on the second interlayer insulating layer ILD2. According to embodiments, the passivation layer PSV may be a via layer. The passivation layer PSV may include an organic material in order to planarize a step difference (or height or thickness difference) thereunder. For example, the passivation layer PSV may include an organic material such as an acrylate resin, an epoxy resin, a phenolic resin, a polyamide resin, a polyimide resin, a polyester resin, a polyphenylene sulfide resin, or benzocyclobutene (BCB). However, the disclosure is not limited thereto, and the passivation layer PSV may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx).

According to embodiments, the sub-pixel SPXL may include the first contact member CNT1 and the second contact member CNT2. The first contact member CNT1 and the second contact member CNT2 may pass through the second interlayer insulating layer ILD2 and the passivation layer PSV. The first electrode ELT1 and the first transistor electrode TE1 may be electrically connected to each other through the first contact member CNT1. The second electrode ELT2 and the power source line PL may be electrically connected to each other through the second contact member CNT2.

The display element layer DPL may be disposed on the pixel circuit layer PCL. The display element layer DPL may include an insulating pattern INP, a first insulating layer INS1, the alignment electrode ELT, the bank BNK, the light emitting element LD, a second insulating layer INS2, the first connection electrode CNE1, the second connection electrode CNE2, and a third insulating layer INS3.

The insulating pattern INP may be disposed on the passivation layer PSV. The insulating pattern INP may have various shapes according to embodiments. In an embodiment, the insulating pattern INP may protrude in the thickness direction (for example, the third direction DR3) of the base layer BSL. The insulating pattern INP may be formed to have an inclined surface inclined at an angle (e.g., a predetermined or selectable angle) with respect to the base layer BSL. However, the disclosure is not limited thereto, and the insulating pattern INP may have a sidewall having a curved surface or a stepped shape. For example, the insulating pattern INP may have a cross-section having a semi-circular or semi-elliptical shape.

The insulating pattern INP may form a step difference (e.g., a predetermined or selectable step difference) so that the light emitting elements LD can be readily aligned in the emission area. According to embodiments, the insulating pattern INP may be a barrier wall.

According to embodiments, a portion of the alignment electrode ELT may be disposed on the insulating pattern INP. For example, the insulating pattern INP may include a first insulating pattern INP1 and a second insulating pattern INP2. The first electrode ELT1 may be disposed on the first insulating pattern INP1, and the second electrode ELT2 may be disposed on the second insulating pattern INP2. Accordingly, a reflective wall may be formed on the insulating pattern INP. Accordingly, light emitted from the light emitting element LD may be recycled to improve light output efficiency of the display device DD (or the pixel PXL).

The insulating pattern INP may include at least one organic material and/or inorganic material. For example, the insulating pattern INP may include an organic material such as an acrylate resin, an epoxy resin, a phenolic resin, a polyamide resin, a polyimide resin, a polyesters resin, a polyphenylene sulfide resin, or benzocyclobutene (BCB). However, the disclosure is not limited thereto, and the insulating pattern INP may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx).

The alignment electrode ELT may be disposed on the passivation layer PSV and/or the insulating pattern INP. As described above, a portion of the alignment electrode ELT may be disposed on the insulating pattern INP to form the reflective wall. The alignment signal (for example, the AC signal and the ground signal) for aligning the light emitting element LD may be supplied to the alignment electrode ELT. According to embodiments, the electrical signal (for example, the anode signal and the cathode signal) may be supplied to the alignment electrode ELT so that the light emitting element LD emits light.

According to embodiments, the alignment electrode ELT may be disposed on a rear surface of the first insulating layer INS1. For example, the alignment electrode ELT may be disposed between the insulating pattern INP or the passivation layer PSV and the first insulating layer INS1. For example, a surface of the alignment electrode ELT may contact the first insulating layer INS1.

The first electrode ELT1 may be electrically connected to the light emitting element LD. The first electrode ELT1 may be electrically connected to the first connection electrode CNE1 through a first contact portion C1 provided in a hole formed in the first insulating layer INS1 and the second insulating layer INS2. The first electrode ELT1 may provide the anode signal so that the light emitting element LD emits light.

The second electrode ELT2 may be electrically connected to the light emitting element LD. The second electrode ELT2 may be electrically connected to the second connection electrode CNE2 through a second contact portion C2 provided in a hole formed in the first insulating layer INS1 and the second insulating layer INS2. The second electrode ELT2 may provide the cathode signal (for example, the ground signal) so that the light emitting element LD emits light.

The first insulating layer INS1 may be disposed on the alignment electrode ELT. For example, the first insulating layer INS1 may cover the first electrode ELT1 and the second electrode ELT2.

The bank BNK may be disposed on the first insulating layer INS1. According to embodiments, the bank BNK may include the first bank BNK1 and the second bank BNK2.

The first bank BNK1 may be disposed on the first insulating layer INS1. According to embodiments, the first bank BNK1 may not overlap the emission area EMA and may overlap the non-emission area NEA in a plan view. As described above, the first bank BNK1 may protrude in the thickness direction (for example, the third direction DR3) of the base layer BSL, and the first bank BNK1 may define the opening OPN. In a process of supplying the light emitting elements LD, a space in which the light emitting elements LD can be provided may be formed in the opening OPN.

The first bank BNK1 may include an organic material such as an acrylate resin, an epoxy resin, a phenolic resin, a polyamide resin, a polyimide resin, a polyesters resin, a polyphenylene sulfide resin, or benzocyclobutene (BCB). However, the disclosure is not limited thereto, and the first bank BNK1 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The second bank BNK2 may be disposed on the first bank BNK1. The second bank BNK2 may protrude in the thickness direction (for example, the third direction DR3) of the base layer BSL, and the second bank BNK2 may define the opening OPN. A space in which the color conversion layer CCL is provided may be formed in the opening OPN.

The second bank BNK2 may include an organic material such as an acrylate resin, an epoxy resin, a phenolic resin, a polyamide resin, a polyimide resin, a polyesters resin, a polyphenylene sulfide resin, or benzocyclobutene (BCB). However, the disclosure is not limited thereto, and the second bank BNK2 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The light emitting element LD may be disposed on the first insulating layer INS1. According to embodiments, the light emitting element LD may emit light based on electrical signals (for example, the anode signal and the cathode signal) provided from the first connection electrode CNE1 and the second connection electrode CNE2.

The light emitting element LD may be disposed in a region surrounded by the first bank BNK1. The light emitting element LD may be disposed between the first insulating pattern INP1 and the second insulating pattern INP2.

The second insulating layer INS2 may be disposed on the light emitting element LD. The second insulating layer INS2 may cover the active layer AL of the light emitting element LD.

The second insulating layer INS2 may expose at least a portion of the light emitting element LD. For example, the second insulating layer INS2 may not cover the first end EP1 and the second end EP2 of the light emitting element LD. Accordingly, the first end EP1 and the second end EP2 of the light emitting element LD may be exposed, and may be electrically connected to the first connection electrode CNE1 and the second connection electrode CNE2, respectively.

In case that a portion of the second insulating layer INS2 is formed on the light emitting elements LD after the light emitting elements LD are aligned, it is possible to prevent the light emitting elements LD from being separated from the aligned positions.

According to embodiments, a portion of the second insulating layer INS2 may be disposed on the first insulating layer INS1. For example, the second insulating layer INS2 may be disposed to overlap the first insulating layer INS1 disposed on the first and second electrodes ELT1 and ELT2 in a plan view.

The second insulating layer INS2 may have a single-layer or multi-layer structure. The second insulating layer INS2 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx). However, the disclosure is not limited to the above-described examples.

The first connection electrode CNE1 and the second connection electrode CNE2 may be disposed on the first insulating layer INS1 and the second insulating layer INS2. The first connection electrode CNE1 may be electrically connected to the first end EP1 of the light emitting element LD. The second connection electrode CNE2 may be electrically connected to the second end EP2 of the light emitting element LD.

The first and second connection electrodes CNE1 and CNE2 may be electrically connected to at least portions of the alignment electrode ELT through the contact portions C1 and C2, respectively. For example, the first connection electrode CNE1 may be electrically connected to the first electrode ELT1 through the first contact portion C1 formed in a region penetrating the first insulating layer INS1 and the second insulating layer INS2. The second connection electrode CNE2 may be electrically connected to the second electrode ELT2 through the second contact portion C2 formed in a region penetrating the first insulating layer INS1 and the second insulating layer INS2. The positions of the first contact portion C1 and the second contact portion C2 are not particularly limited.

The first connection electrode CNE1 and the second connection electrode CNE2 may include a transparent conductive material. For example, the first connection electrode CNE1 and the second connection electrode CNE2 may include at least one selected from the group consisting of indium tin oxide (ITO), indium zinc oxide (IZO), and indium tin zinc oxide (ITZO). Accordingly, light emitted from the light emitting elements LD may pass through the first and second connection electrodes CNE1 and CNE2 to be emitted to outside of the display device DD. However, the disclosure is not limited to the above-described examples.

According to embodiments, the first connection electrode CNE1 and the second connection electrode CNE2 may be patterned at a same time in a same process. However, the disclosure is not limited to the above-described examples. After at least one of the first connection electrode CNE1 and the second connection electrode CNE2 is patterned, the other electrode may be patterned.

The third insulating layer INS3 may be disposed on the first and second connection electrodes CNE1 and CNE2 and the second insulating layer INS2. The third insulating layer INS3 may protect components of the display element layer DPL from external influences.

The third insulating layer INS3 may have a single-layer or multi-layer structure. The third insulating layer INS3 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A configuration of the pixel PXL including the color conversion layer CCL will be described with reference to FIGS. 6 and 7. FIG. 6 illustrates the color conversion layer CCL, the optical layer OPL, the color filter layer CFL, and the like. For convenience of description, components other than the second bank BNK2 of the pixel circuit layer PCL and the display element layer DPL among the above-described components are omitted in FIG. 6. FIG. 7 illustrates a stacked structure of the pixel PXL in relation to the color conversion layer CCL, the optical layer OPL, and the color filter layer CFL.

Referring to FIGS. 6 and 7, the second bank BNK2 may be disposed between or at a boundary between the first to third sub-pixels SPXL1, SPXL2, and SPXL3, and may define spaces (regions) overlapping the first to third sub-pixels SPXL1, SPXL2, and SPXL3, respectively. The spaces defined by the second bank BNK2 may be regions in which the color conversion layer CCL may be provided.

The color conversion layer CCL may be disposed on the light emitting elements LD in a space surrounded by the second bank BNK2. The color conversion layer CCL may include a first color conversion layer CCL1 disposed in the first sub-pixel SPXL1, a second color conversion layer CCL2 disposed in the second sub-pixel SPXL2, and a scattering layer LSL disposed in the third sub-pixel SPXL3.

The color conversion layer CCL may be disposed on the light emitting element LD. The color conversion layer CCL may be configured to change the wavelength of light. In an embodiment, the first to third sub-pixels SPXL1, SPXL2, and SPXL3 may include light emitting elements LD emitting light of a same color. For example, the first to third sub-pixels SPXL1, SPXL2, and SPXL3 may include light emitting elements LD emitting light of the third color (or blue). A full-color image may be displayed by disposing the color conversion layer CCL including color conversion particles on each of the first to third sub-pixels SPXL1, SPXL2, and SPXL3.

The first color conversion layer CCL1 may include first color conversion particles that convert light of the third color emitted from the light emitting element LD into light of the first color. For example, the first color conversion layer CCL1 may include first quantum dots QD1 dispersed in a matrix material (e.g., a predetermined or selectable matrix material) such as a base resin.

In an embodiment, in case that the light emitting element LD is a blue light emitting element emitting blue light and the first sub-pixel SPXL1 is a red pixel, the first color conversion layer CCL1 may include the first quantum dots QD1 that convert blue light emitted from the blue light emitting element into red light. The first quantum dots QD1 may absorb blue light and shift the wavelength according to energy transition to emit red light. In case that the first sub-pixel SPXL1 is a pixel of a different color, the first color conversion layer CCL1 may include the first quantum dots QD1 corresponding to the color of the first sub-pixel SPXL1.

The second color conversion layer CCL2 may include second color conversion particles that convert light of the third color emitted from the light emitting element LD into light of the second color. For example, the second color conversion layer CCL2 may include second quantum dots QD2 dispersed in a matrix material (e.g., a predetermined or selectable matrix material) such as a base resin.

In an embodiment, in case that the light emitting element LD is a blue light emitting element emitting blue light and the second sub-pixel SPXL2 is a green pixel, the second color conversion layer CCL2 may include the second quantum dots QD2 that convert blue light emitted from the blue light emitting element into green light. The second quantum dots QD2 may absorb blue light and shift the wavelength according to energy transition to emit green light. In case that the second sub-pixel SPXL2 is a pixel of a different color, the second color conversion layer CCL2 may include the second quantum dots QD2 corresponding to the color of the second sub-pixel SPXL2.

In an embodiment, since blue light having a relatively short wavelength in the visible light region is incident on the first quantum dots QD1 and the second quantum dots QD2, respectively, absorption coefficients of the first quantum dots QD1 and the second quantum dots QD2 may be increased. Accordingly, the efficiency of light finally emitted from the first sub-pixel SPXL1 and the second sub-pixel SPXL2 may be improved, and excellent color reproducibility may be secured. The manufacturing efficiency of the display device DD may be improved by configuring the emission parts EMU of the first to third sub-pixels SPXL1, SPXL2, and SPXL3 using light emitting elements LD of a same color (for example, blue light emitting elements).

The scattering layer LSL may be provided to efficiently use the light of the third color (or blue) emitted from the light emitting element LD. For example, in case that the light emitting element LD is a blue light emitting element emitting blue light and the third sub-pixel SPXL3 is a blue pixel, the scattering layer LSL may include at least one type of scatterers SCT in order to efficiently use the light emitted from the light emitting element LD. For example, the scatterers SCT of the scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). The scatterers SCT are not disposed only in the third sub-pixel SPXL3, and may also be selectively included in the first color conversion layer CCL1 or the second color conversion layer CCL2. According to embodiments, the scatterers SCT may be omitted and the scattering layer LSL made of a transparent polymer may be provided.

A first capping layer CPL1 may be disposed on the color conversion layer CCL. The first capping layer CPL1 may be provided over the first to third sub-pixels SPXL1, SPXL2, and SPXL3. The first capping layer CPL1 may cover the color conversion layer CCL. The first capping layer CPL1 may prevent impurities such as moisture or air from penetrating from outside to damage or contaminate the color conversion layer CCL.

The first capping layer CPL1 may be an inorganic layer, and may include silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

The optical layer OPL may be disposed on the first capping layer CPL1. The optical layer OPL may serve to improve light extraction efficiency by recycling light, provided from the color conversion layer CCL, by total reflection. To this end, the optical layer OPL may have the refractive index relatively lower than that of the color conversion layer CCL. For example, the refractive index of the color conversion layer CCL may be about 1.6 to about 2.0, and the refractive index of the optical layer OPL may be about 1.1 to about 1.3.

A second capping layer CPL2 may be disposed on the optical layer OPL. The second capping layer CPL2 may be provided over the first to third sub-pixels SPXL1, SPXL2, and SPXL3. The second capping layer CPL2 may cover the optical layer OPL. The second capping layer CPL2 may prevent impurities such as moisture or air from penetrating from outside to damage or contaminate the optical layer OPL.

The second capping layer CPL2 may be an inorganic layer, and may include silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

A planarization layer PLL may be disposed on the second capping layer CPL2. The planarization layer PLL may be provided over the first to third sub-pixels SPXL1, SPXL2, and SPXL3.

The planarization layer PLL may include an organic material such as an acrylic resin, an epoxy resin, a phenolic resin, a polyamide resin, a polyimide resin, a polyester resin, a polyphenylene sulfide resin, or benzocyclobutene (BCB). However, the disclosure is not limited thereto, and the planarization layer PLL may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The color filter layer CFL may be disposed on the planarization layer PLL. The color filter layer CFL may include color filters CF1, CF2, and CF3 matching the color of each pixel PXL. A full-color image may be displayed by disposing the color filters CF1, CF2, and CF3 matching the colors of the first to third sub-pixels SPXL1, SPXL2, and SPXL3, respectively.

The color filter layer CFL may include a first color filter CF1 disposed in the first sub-pixel SPXL1 to selectively transmit light emitted from the first sub-pixel SPXL1, a second color filter CF2 disposed in the second sub-pixel SPXL2 to selectively transmit light emitted from the second sub-pixel SPXL2, and a third color filter CF3 disposed in the third sub-pixel SPXL3 to selectively transmit light emitted from the third sub-pixel SPXL3.

In embodiments, the first color filter CF1, the second color filter CF2, and the third color filter CF3 may be a red color filter, a green color filter, and a blue color filter, respectively. However, the disclosure is not limited thereto. Hereinafter, when referring to any color filter among the first color filter CF1, the second color filter CF2, and the third color filter CF3, or generically referring to two or more types of color filters, they will be referred to as “color filter CF” or “color filters CF”.

The first color filter CF1 may overlap the first color conversion layer CCL1 in a thickness direction (for example, the third direction DR3) of a substrate. The first color filter CF1 may include a color filter material that selectively transmits light of the first color (or red). For example, in case that the first sub-pixel SPXL1 is a red pixel, the first color filter CF1 may include a red color filter material.

The second color filter CF2 may overlap the second color conversion layer CCL2 in the thickness direction (for example, the third direction DR3) of the substrate. The second color filter CF2 may include a color filter material that selectively transmits light of the second color (or green). For example, in case that the second sub-pixel SPXL2 is a green pixel, the second color filter CF2 may include a green color filter material.

The third color filter CF3 may overlap the scattering layer LSL in the thickness direction (for example, the third direction DR3) of the substrate. The third color filter CF3 may include a color filter material that selectively transmits light of the third color (or blue). For example, in case that the third sub-pixel SPXL3 is a blue pixel, the third color filter CF3 may include a blue color filter material.

According to embodiments, a light blocking layer BM may be further disposed between the first to third color filters CF1, CF2, and CF3. As such, in case that the light blocking layer BM is formed between the first to third color filters CF1, CF2, and CF3, color mixing defects visually recognized from the front or side of the display device DD can be prevented. The material of the light blocking layer BM is not particularly limited, and the light blocking layer BM may be composed of various light blocking materials. For example, the light blocking layer BM may include a black matrix or may be implemented by stacking the first to third color filters CF1, CF2, and CF3 on each other.

An overcoat layer OC may be disposed on the color filter layer CFL. The overcoat layer OC may be provided over the first to third sub-pixels SPXL1, SPXL2, and SPXL3. The overcoat layer OC may cover a lower member including the color filter layer CFL. The overcoat layer OC may prevent moisture or air from penetrating into the above-described lower member. The overcoat layer OC may protect the above-described lower member from foreign substances such as dust.

The overcoat layer OC may include an organic material such as an acrylic resin, an epoxy resin, a phenolic resin, a polyamide resin, a polyimide resin, a polyester resin, a polyphenylene sulfide resin, or benzocyclobutene (BCB). However, the disclosure is not limited thereto, and the overcoat layer OC may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The outer film layer OFL may be disposed on the overcoat layer OC. The outer film layer OFL may be disposed outside the display device DD to reduce external influences. The outer film layer OFL may be provided over the first to third sub-pixels SPXL1, SPXL2, and SPXL3. According to embodiments, the outer film layer OFL may include at least one of a polyethyleneterephthalate (PET) film, a low-reflection film, a polarizing film, and a transmittance-controllable film, but the disclosure is not limited thereto. According to embodiments, the pixel PXL may include an upper substrate instead of the outer film layer OFL.

Hereinafter, the alignment electrode ELT and components adjacent to the alignment electrode ELT will be described with reference to FIGS. 8 and 9. Repetitive contents with respect to the above-described contents will be briefly described or will not be repeatedly described.

FIG. 8 is a cross-sectional view schematically illustrating an alignment electrode according to an embodiment. FIG. 8 illustrates an embodiment in which the alignment electrode ELT has a multi-layer (for example, double-layer) structure. FIG. 9 is an enlarged view schematically illustrating area EA1 of FIG. 5. FIG. 9 illustrates a connection relationship between the alignment electrode ELT and the components adjacent to the alignment electrode ELT. For convenience of description, in FIG. 9, the first and second connection electrodes CNE1 and CNE2 are collectively referred to as a connection electrode CNE.

Referring to FIGS. 8 and 9, the alignment electrode ELT may include two or more different layers. For example, the alignment electrode ELT may include the first layer 120 and the second layer 140. According to embodiments, the first layer 120 may be a layer facing the base layer BSL among the layers of the alignment electrode ELT, and the second layer 140 may be a layer facing the light emitting elements LD among the layers of the alignment electrode ELT. The first layer 120 may be more adjacent to the base layer BSL than the second layer 140. The second layer 140 may be more adjacent to the light emitting elements LD than the first layer 120.

The first layer 120 and the second layer 140 may overlap each other in a plan view. The first layer 120 and the second layer 140 may contact each other. For example, after a conductive material for forming the first layer 120 is patterned, a conductive material for forming the second layer 140 may be patterned.

At least a portion of the first layer 120 may not overlap the second layer 140 in a plan view. For example, the second layer 140 may expose a portion of the first layer 120. According to embodiments, the second layer 140 may not cover the portion of the first layer 120, and the exposed portion of the first layer 120 may be electrically connected to the connection electrode CNE. For example, the exposed portion of the first layer 120 may physically contact the connection electrode CNE.

A first thickness 122 of the first layer 120 and a second thickness 124 of the second layer 140 may be different from each other. The first thickness 122 may be greater than the second thickness 124. According to embodiments, the first thickness 122 may be at least twice the second thickness 124.

The first layer 120 may be a connection portion electrically connected to the connection electrodes CNE1 and CNE2 and wirings (for example, the first and second transistor electrodes TE1 and TE2, the power source line PL, or the like) of the pixel circuit layer PCL. The second layer 140 may be a protective portion for protecting the first layer 120. Accordingly, in a process of manufacturing alignment electrodes ELT, a portion of the second layer 140 may be removed. The second thickness 124 may be less than the first thickness 122 so that a process of removing the portion of the second layer 140 may be readily performed.

According to embodiments, the first thickness 122 may be about 1000 Å to about 4000 Å. According to embodiments, the first thickness 122 may be about 1500 Å to about 3000 Å. The second thickness 124 may be about 100 Å to about 500 Å. According to embodiments, the second thickness 124 may be about 200 Å to about 400 Å. However, the disclosure is not limited to the above-described examples.

The first layer 120 and the second layer 140 may include different materials. For example, each of the first layer 120 and the second layer 140 may include materials suitable for performing a desired function.

The first layer 120 may be an electrode layer physically contacting the connection electrode CNE to be electrically connected to the connection electrode CNE. For example, the first insulating layer INS1, the second insulating layer INS2, and the second layer 140 may form a hole H exposing the first layer 120, and at least a portion of the connection electrode CNE may be provided in the hole H to be electrically connected to the first layer 120.

According to embodiments, the first layer 120 and the connection electrode CNE may physically contact each other. According to embodiments, the connection electrode CNE may not physically contact the second layer 140 (for example, may be spaced apart from the second layer 140 with another layer interposed therebetween) and may physically contact the first layer 120. A difference between a corrosion potential of a conductive material for forming the first layer 120 and a corrosion potential of a conductive material for forming the connection electrode CNE may be less than or equal to a potential difference (e.g., a predetermined or selectable potential difference). The potential difference may be determined by the corrosion potential of the material forming the first layer 120 and the corrosion potential of the material forming the connection electrode CNE. According to embodiments, the first layer 120 may include a material having a corrosion potential different from that of the material for forming the connection electrode CNE within 1.0 V. For example, in case that the connection electrode CNE includes a transparent conductive material (for example, indium tin oxide (ITO)), the first layer 120 may include a molybdenum-based material. For example, the first layer 120 may include at least one selected from the group consisting of molybdenum (Mo), molybdenum-niobium (MoNb), and molybdenum-tungsten (MoW). However, the disclosure is not limited thereto.

According to embodiments, the potential difference may be about 1.0 V or less. For example, the predetermined potential difference may be about 0.1 V to about 0.7 V. According to embodiments, the potential difference may be about 0.2 V to about 0.6 V. According to embodiments, the potential difference may be about 0.23 V to about 0.53 V. Experimentally, in case that the potential difference is greater than about 1.0 V, a galvanic corrosion reaction may occur between electrodes, which may cause damage to the electrodes. However, according to embodiments, the potential difference defined between the first layer 120 and the connection electrode CNE can be controlled to be less than about 1.0 V, and thus damage to the first layer 120 and the connection electrode CNE can be substantially prevented. Since the galvanic corrosion reaction is prevented as described above, an excessive increase in a resistance value between the first layer 120 and the connection electrode CNE can be prevented. For example, according to embodiments, the resistance value between the first layer 120 and the connection electrode CNE may be about 10³Ω or less.

Side surfaces of the first insulating layer INS1 and the second layer 140 may be covered by the second insulating layer INS2. For example, in a region adjacent to the hole H, outer surfaces of the first insulating layer INS1 and the second layer 140 may be entirely covered by the second insulating layer INS2 and may not be exposed. According to embodiments, a side surface of the second insulating layer INS2 may be directly adjacent to the hole H.

The second layer 140 may be an electrode layer for protecting the first layer 120 from external influences in a process of manufacturing the display device DD. The second layer 140 may be a sacrificial layer of which at least a portion is removed to form a region in which the first layer 120 electrically contacts the connection electrode CNE, while protecting the first layer 120. The second layer 140 may be a reflective layer for improving light efficiency of the pixel PXL by recycling light emitted from the light emitting elements LD. Accordingly, the second layer 140 may include a material having excellent chemical resistance and excellent reflectance. To this end, according to embodiments, the second layer 140 may include an aluminum-based material. For example, the second layer 140 may include at least one selected from the group consisting of aluminum (Al), aluminum-titanium (AlTi), and aluminum-neodymium (AlNd).

According to embodiments, the second layer 140 may be spaced apart from the base layer BSL as compared to the first layer 120 to cover at least one surface of the first layer 120. Accordingly, the second layer 140 may block materials that may damage the first layer 120 from the first layer 120. For example, in a process of performing a photolithography process to form the display element layer DPL (for example, re-work progress), a problem in which the first layer 120 is exposed to a developer may be prevented. Accordingly, damage to the first layer 120 electrically connected to the connection electrode CNE can be prevented, and as a result, distortion of an electrical signal provided to the light emitting element LD can be substantially prevented.

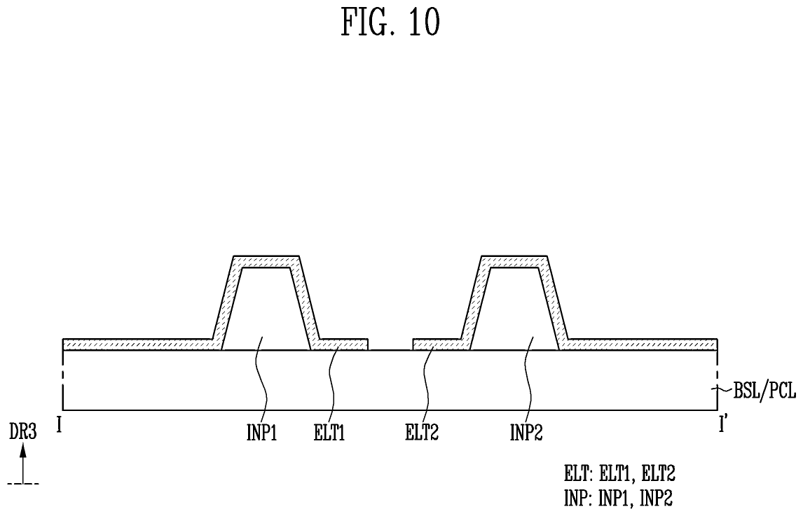

A method of manufacturing the display device DD according to embodiments will be described with reference to FIGS. 10 to 24. Repetitive contents with respect to the above-described contents will be briefly described or will be omitted.

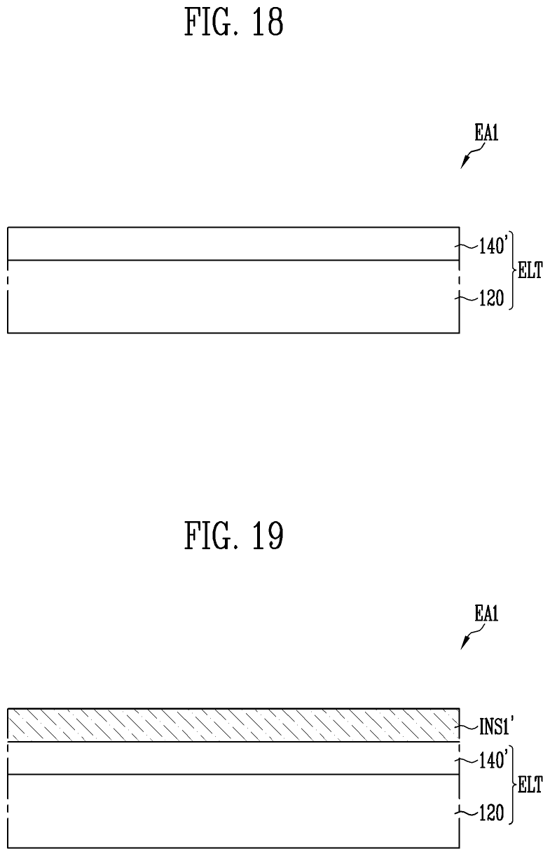

FIGS. 10 to 24 are cross-sectional views schematically illustrating a method of manufacturing a display device according to embodiments in each process step. FIGS. 10 to 17 illustrate the cross-sectional structure described above with reference to FIG. 5. FIGS. 18 to 24 illustrate the cross-sectional structure described above with reference to FIG. 9. In FIGS. 10 to 17, the base layer BSL and the pixel circuit layer PCL are briefly shown for convenience of description.

Referring to FIGS. 10 and 18, the base layer BSL may be provided (or prepared), and the pixel circuit layer PCL may be disposed on the base layer BSL. The insulating pattern INP may be disposed (or patterned) on the pixel circuit layer PCL, the alignment electrodes ELT may be disposed (or patterned) on the insulating pattern INP.

In this phase, components (for example, the pixel circuit layer PCL and the like) disposed on the base layer BSL may be formed by patterning a conductive layer (or a metal layer), an inorganic material, an organic material, or the like through a conventional process using a mask.

In this phase, the first layer 120 and a second layer 140′ may be sequentially patterned to form the alignment electrode ELT. As described above, the first layer 120 may be patterned thicker than the second layer 140′, and may be formed before the second layer 140′.

In this phase, the alignment electrode ELT may be deposited on insulating patterns INP to form the reflective wall. The first electrode ELT1 and the second electrode ELT2 constituting the alignment electrode ELT may be patterned to be spaced apart from each other in a direction. Accordingly, a region in which the light emitting elements LD are to be disposed may be defined between the first electrode ELT1 and the second electrode ELT2.

In this phase, in a process of forming the alignment electrode ELT, the first layer 120 of the alignment electrode ELT may be protected by the second layer 140′. For example, as described above, the second layer 140′ may prevent a developer used in a process (for example, rework) of patterning the alignment electrode ELT from being applied to the first layer 120. The first layer 120 may be a conductive layer to which an electrical signal is applied so that the light emitting elements LD emit light. Due to the multi-layer structure including the first layer 120 and the second layer 140′, damage to the first layer 120 can be substantially prevented, and reliability of the electrical signal can be improved.

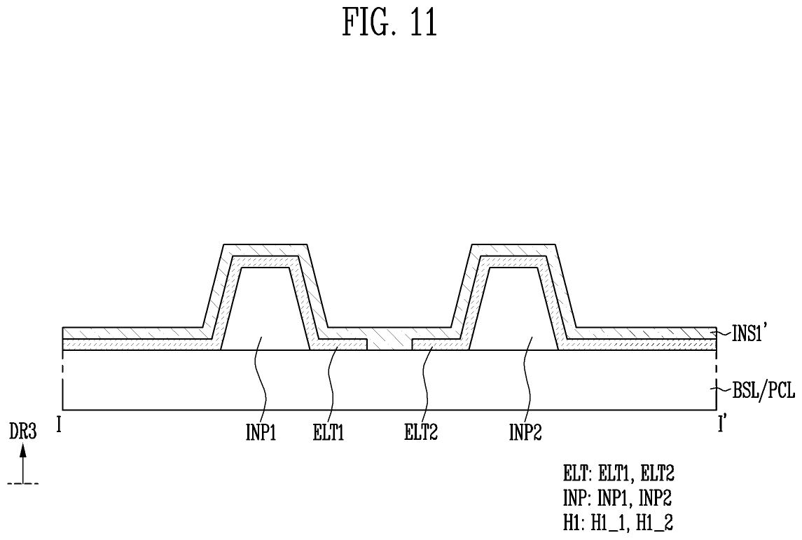

Referring to FIGS. 11 and 19, a first insulating layer INS1′ may be disposed (or deposited) on the alignment electrodes ELT.

In this phase, the first insulating layer INS1′ may cover the alignment electrode ELT. For example, the first insulating layer INS1′ may be disposed on the second layer 140′ of the alignment electrode ELT. The first insulating layer INS1′ may form a surface on which the light emitting elements LD are disposed.

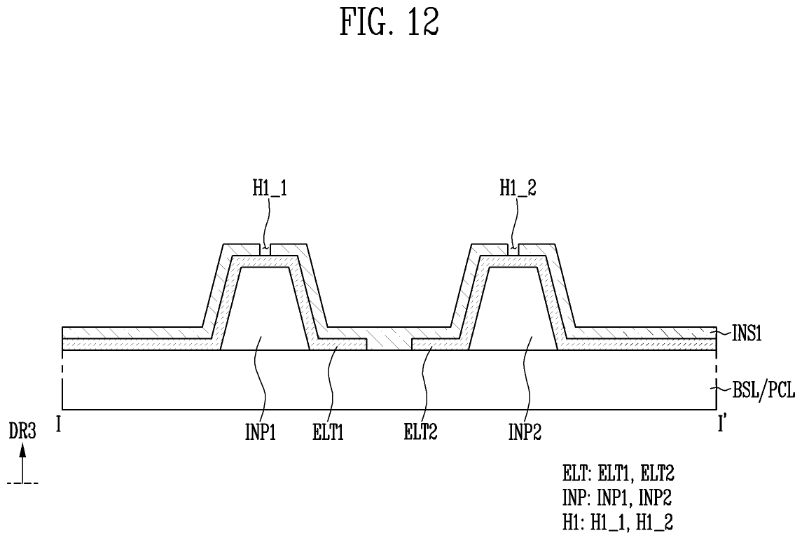

Referring to FIGS. 12 and 20, at least a portion of the first insulating layer INS1′ may be removed to form a first hole H1.

In this phase, the first insulating layer INS1 may form the first hole H1. For example, the first hole H1 may include a (1_1)th hole H1_1 and a (1_2)th hole H1_2. The (1_1)th hole H1_1 may overlap the first electrode ELT1, and the (1_2)th hole H1_2 may overlap the second electrode ELT2. According to embodiments, the first insulating layer INS1 may expose the second layer 140′ in the first hole H1.

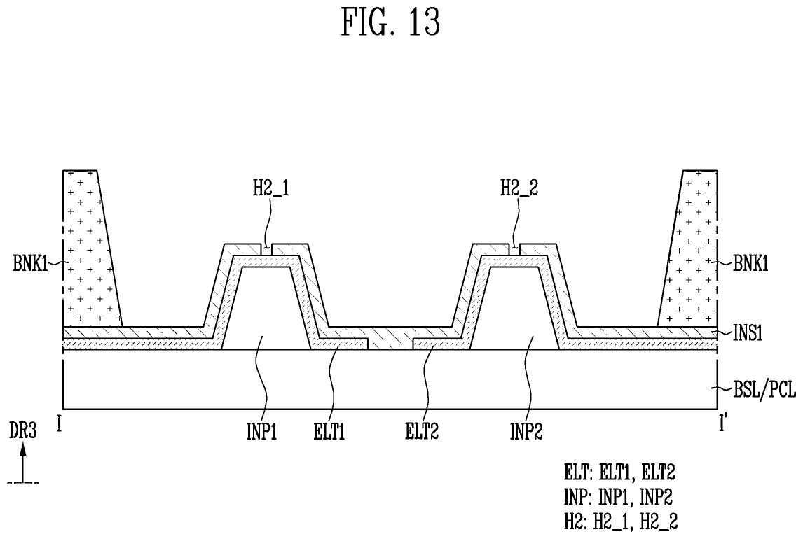

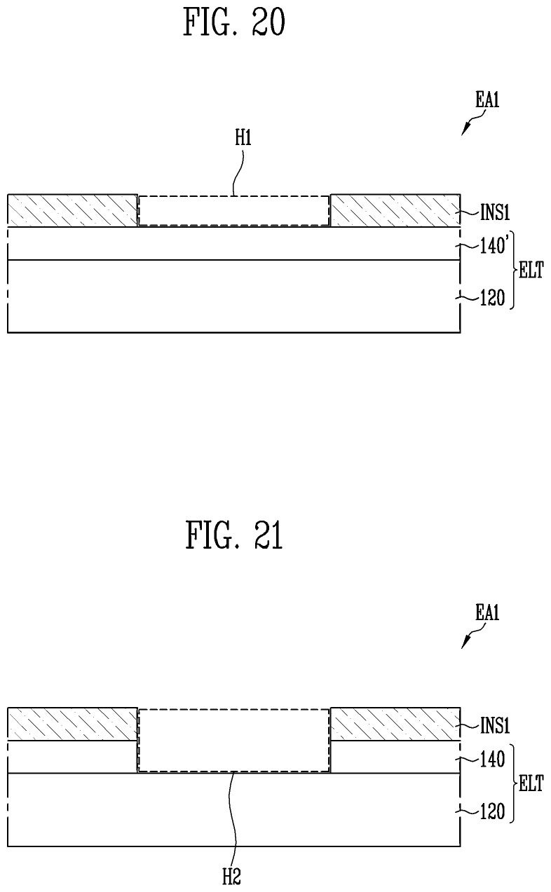

Referring to FIGS. 13 and 21, the first bank BNK1 may be disposed on the first insulating layer INS1, and at least a portion of the second layer 140′ may be removed. The first bank BNK1 may define a space to which a fluid may be supplied.

In this phase, the first bank BNK1 may define a space in which a fluid may be accommodated. For example, a portion of the first bank BNK1 may be adjacent to a region in which the first electrode ELT1 is disposed, and another portion of the first bank BNK1 may be adjacent to a region in which the second electrode ELT2 is disposed. Accordingly, the first bank BNK1 may be disposed to surround a region.

In this phase, at least a portion of the second layer 140′ may be removed to form a second hole H2. For example, the second hole H2 may include a (2_1)th hole H2_1 and a (2_2)th hole H2_2. The (2_1)th hole H2_1 may overlap the first electrode ELT1, and the (2_2)th hole H2_2 may overlap the second electrode ELT2. According to embodiments, the second layer 140 may expose the first layer 120 in the second hole H2.

Referring to FIG. 14, the light emitting elements LD may be disposed (or aligned) on the first insulating layer INS1.

In this phase, the ink INK including the light emitting elements LD may be supplied to the space which is defined by the first bank BNK1 and in which the fluid may be accommodated. For example, the ink INK including the light emitting elements LD and a solvent SLV may be supplied on the base layer BSL by a printing device configured to eject a fluid. According to embodiments, the solvent SLV may include an organic solvent. For example, the solvent SLV may be at least one of Propylene Glycol Methyl Ether Acetate (PGMEA), Dipropylen Glycol n-Propyl Ether (DGPE), and Triethylene Gylcol n-Butyl Ether (TGBE). However, the disclosure is not limited to the above-described examples.

In this phase, the ink INK may be accommodated in the space defined by the first bank BNK1, and the alignment signals may be supplied to the alignment electrodes ELT. The light emitting elements LD may be aligned based on an electric field according to the alignment signals. As described above, the first alignment signal may be supplied to the first electrode ELT1 and the second alignment signal may be supplied to the second electrode ELT2, so that the light emitting elements LD may be aligned between the first electrode ELT1 and the second electrode ELT2. Thereafter, the solvent SLV may be removed.

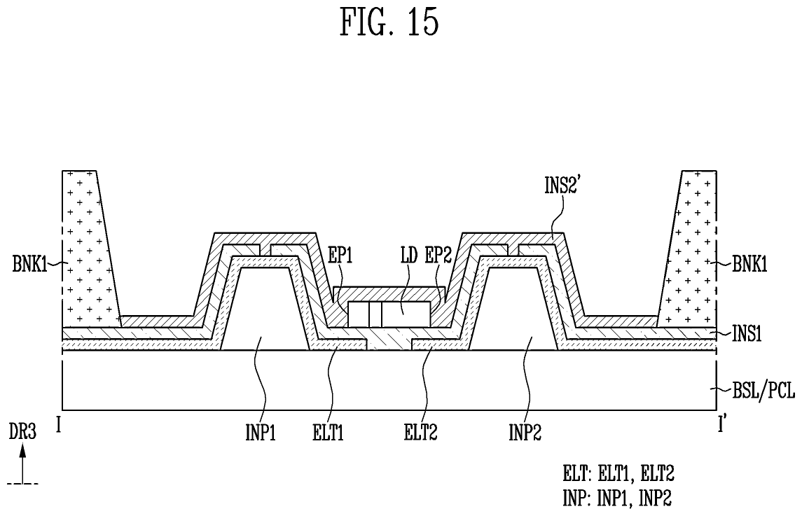

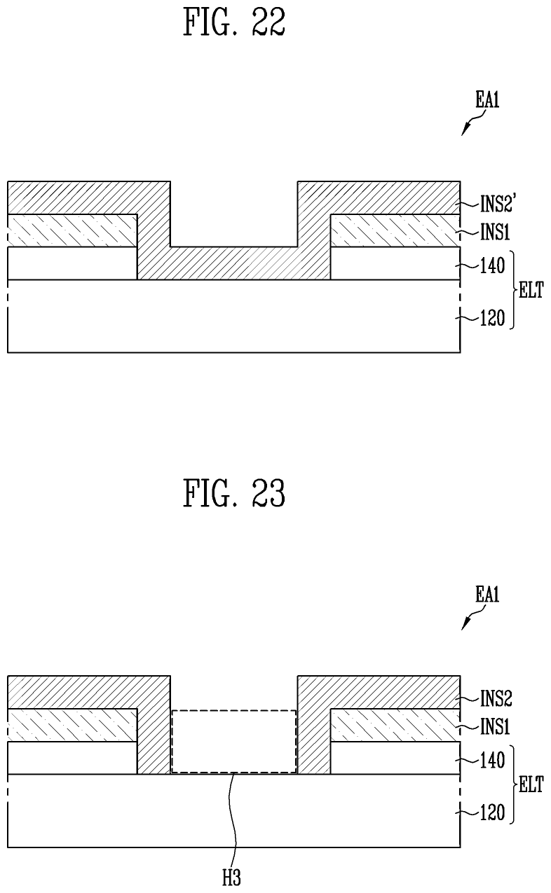

Referring to FIGS. 15 and 22, a second insulating layer INS2′ may be disposed (or deposited). For example, the second insulating layer INS2′ may be disposed on the light emitting elements LD, the first insulating layer INS1, and the alignment electrodes ELT.

In this phase, a portion of the second insulating layer INS2′ may cover the active layer AL of the light emitting element LD. Another portion of the second insulating layer INS2′ may be provided in the second hole H2. Accordingly, the second insulating layer INS2′ may cover the exposed first layer 120. In this phase, the second insulating layer INS2′ may cover side surfaces of the second layer 140 and the first insulating layer INS1.

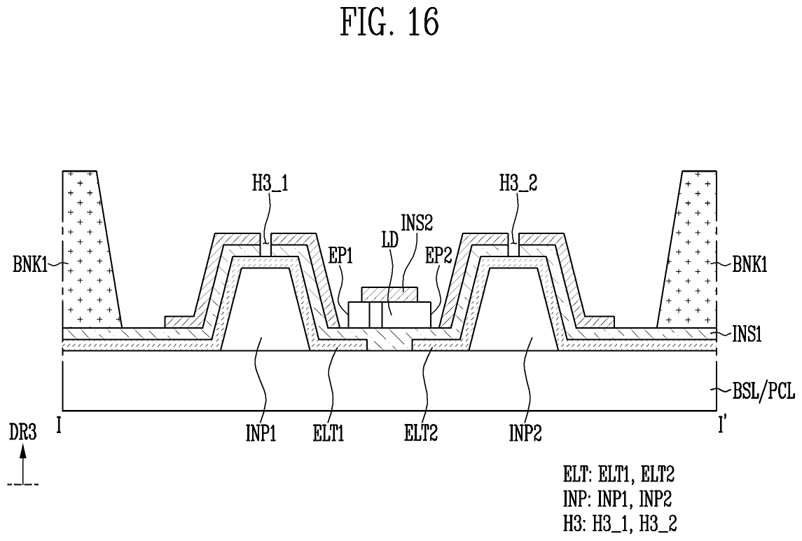

Referring to FIGS. 16 and 23, at least a portion of the second insulating layer INS2′ may be removed to form a third hole H3.

In this phase, the second insulating layer INS2 may form the third hole H3. For example, the third hole H3 may include a (3_1)th hole H3_1 and a (3_2)th hole H3_2. The (3_1)th hole H3_1 may overlap the first electrode ELT1, and the (3_2)th hole H3_2 may overlap the second electrode ELT2. According to embodiments, the second insulating layer INS2 may expose the first layer 120 in the third hole H3.

In this phase, the second insulating layer INS2 may expose the first end EP1 and the second end EP2 of the light emitting element LD.

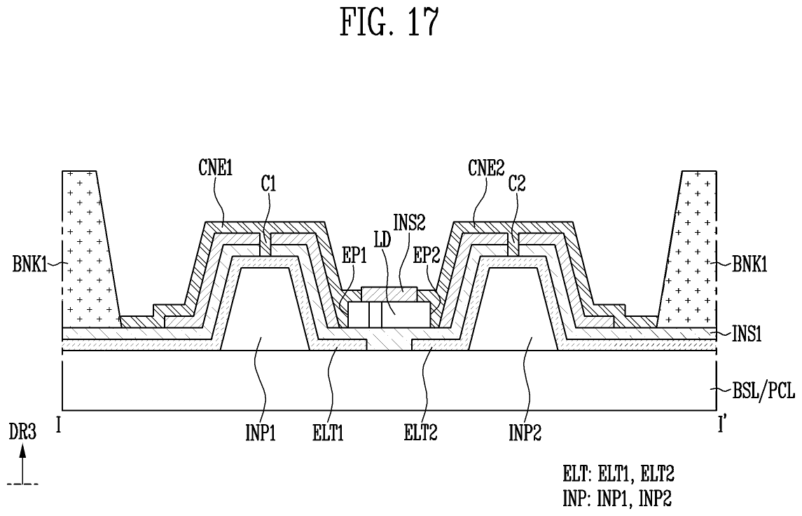

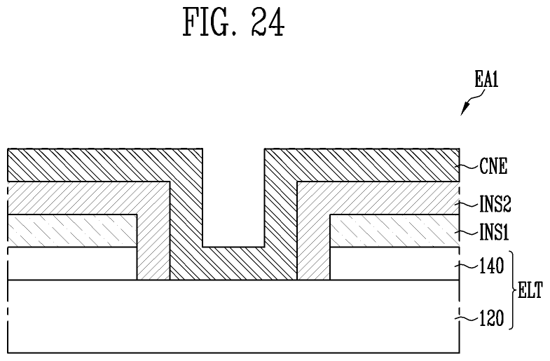

Referring to FIGS. 17 and 24, the connection electrode CNE may be patterned.

In this phase, the connection electrode CNE may be electrically connected to the light emitting elements LD. For example, the first connection electrode CNE1 may be electrically connected to the first end EP1 of the light emitting elements LD, and the second connection electrode CNE2 may be connected to the second end EP2 of the light emitting elements LD.

In this phase, the connection electrode CNE may be electrically connected to the first layer 120. For example, the connection electrode CNE may physically contact the first layer 120. According to embodiments, the connection electrode CNE may be separated from the first layer 120 by the second insulating layer INS2.

As described above, a difference between corrosion potentials of materials for forming the connection electrode CNE and the first layer 120 may be less than or equal to the potential difference (e.g., a predetermined or selectable potential difference). Accordingly, even in case that the connection electrode CNE and the first layer 120 contact each other, a corrosion reaction can be substantially prevented. Accordingly, distortion of the electrical signal applied to the connection electrode CNE can be substantially prevented.

Thereafter, although not shown in the drawings, the color conversion layer CCL and the color filter layer CFL may be provided. Accordingly, the display device DD according to the embodiments may be manufactured.

According to the embodiments of the disclosure, a display device capable of preventing damage to electrodes and improving reliability of an electrical signal, and a method of manufacturing the same can be provided.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
electrodes on a base layer;
a first insulating layer on the electrodes;
a light emitting element on the first insulating layer; and
a connection electrode electrically connecting the light emitting element and at least a portion of the electrodes, wherein
each of the electrodes includes a first layer and a second layer on the first layer, and
the first layer is electrically connected to the connection electrode through a contact portion formed in a region penetrating the first insulating layer and the second layer.

2. The display device of claim 1, wherein
the first layer is more adjacent to the base layer than the second layer,
the second layer is more adjacent to the light emitting element than the first layer, and
the first layer and the second layer contacts with each other.

3. The display device of claim 1, wherein
the second layer exposes a region of the first layer, and
the connection electrode physically contacts with the first layer in the region.

4. The display device of claim 3, wherein the connection electrode does not physically contact the second layer in a region adjacent to the region.

5. The display device of claim 3, further comprising:
a second insulating layer on the first insulating layer,
wherein the second insulating layer covers a side surface of the first insulating layer and the second layer in a region adjacent to the region of the first layer exposed by the second layer.

6. The display device of claim 1, wherein a first thickness of the first layer is greater than a second thickness of the second layer.

7. The display device of claim 6, wherein the first thickness is at least twice the second thickness.

8. The display device of claim 6, wherein
the first thickness is in a range of about 1000 Å to about 4000 Å, and
the second thickness is in a range of about 100 Å to about 500 Å.

9. The display device of claim 1, wherein the first layer includes at least one selected from a group consisting of molybdenum (Mo), molybdenum-niobium (MoNb), and molybdenum-tungsten (MoW).

10. The display device of claim 1, wherein the second layer includes at least one selected from a group consisting of aluminum (Al), aluminum-titanium (AlTi), and aluminum-neodymium (AlNd).

11. The display device of claim 1, wherein the connection electrode includes at least one selected from a group consisting of indium tin oxide (ITO), indium zinc oxide (IZO), and indium tin zinc oxide (ITZO).

12. The display device of claim 1, wherein
a corrosion potential of a material for forming the first layer and a corrosion potential of a material for forming the connection electrode are different by a potential difference, and
the potential difference is about 1.0V or less.

13. The display device of claim 12, wherein the potential difference is in a range of about 0.2V to about 0.6V.

14. The display device of claim 1, wherein a resistance value between the first layer and the connection electrode is about 10³Ω or less.

15. A display device comprising:
electrodes on a base layer and including a first layer and a second layer;
a first insulating layer on the electrodes;
a light emitting element on the first insulating layer;
a second insulating layer on the first insulating layer; and
a connection electrode electrically connecting the electrodes and the light emitting element, wherein
the second layer and the first insulating layer form a hole exposing the first layer,
the second insulating layer covers a side surface of the first insulating layer and the second layer adjacent to the hole, and
the connection electrode does not physically contact with the second layer, without being physically contacted with the first layer through a contact portion formed in the hole.

16. A method of manufacturing a display device comprising:
patterning electrodes on a base layer;
disposing a first insulating layer on the electrodes;
disposing a light emitting element on the first insulating layer; and
patterning a connection electrode electrically connecting the light emitting element and the electrodes, wherein
the patterning the electrodes includes sequentially patterning a first layer and a second layer, and
the patterning the connection electrode includes electrically connecting the connection electrode to the first layer through a contact portion formed in a region penetrating the first insulating layer and the second layer.

17. The method of claim 16, wherein
the electrodes include a first electrode and a second electrode spaced apart from the first electrode, and
the disposing of the light emitting element includes:
supplying a first alignment signal to the first electrode and supplying a second alignment signal to the second electrode; and
aligning the light emitting element between the first electrode and the second electrode based on an electric field according to the first alignment signal and the second alignment signal.

18. The method of claim 16, further comprising:
forming a first hole by the first insulating layer;
forming a second hole by the second layer;
disposing a second insulating layer on the first insulating layer; and
forming a third hole by the second insulating layer, wherein
the disposing of the second insulating layer includes covering a side surface of the second layer and the first insulating layer by the second insulating layer in a region adjacent to the second hole, and
the forming of the third hole includes exposing the first layer by the second insulating layer.

19. The method of claim 18, further comprising:
forming a bank on the first insulating layer,
wherein the forming of the bank and the forming of the first hole are performed in a same process.

20. The method of claim 16, wherein
a corrosion potential of a material for forming the first layer and a corrosion potential of a material for forming the connection electrode are different by a potential difference, and
the potential difference is about 1.0V or less.
